(19) United States
(12) Patent Application Publication
(10) Pub. No.: US 2016/0043286 A1
(43) Pub. Date: Feb. 11, 2016

(54) ARRANGEMENT FOR CONVERTING LIGHT EMITTED BY AN LED LIGHT SOURCE

(71) Applicant: ZUMTOBEL LIGHTING GMBH, Dornbirn (AT)

(72) Inventors: Johann ZEHETNER, Dornbirn (AT); David SCHMIDMAYR, Dornbirn (AT)

(73) Assignee: Zumtobel Lighting GMBH, Dornbirn (AT)

(21) Appl. No.: 14/781,837

(22) PCT Filed: Apr. 1, 2014
(86) PCT No.: PCT/EP2014/056531

§ 371 Date: Oct. 1, 2015

(30) Foreign Application Priority Data
Apr. 2, 2013 (DE) 20 2013 101 400.1

(51) Int. Cl. H01L 33/50; H01L 33/60; H01L 33/58

(52) U.S. Cl. CPC H01L 33/502; H01L 33/58; H01L 33/60; H01L 33/505

(57) ABSTRACT

An arrangement for converting light emitted by an LED-light source. The arrangement includes a color conversion element which is designed to convert at least partially the light coming from an LED-light source into another wavelength, and a preferably plate-shaped light emission element which is arranged downstream of the color conversion element. The plate-shaped light emission element forms on one side facing away from the color conversion element, a structured light emission surface.

The present invention relates to an arrangement for converting the light emitted by an LED light source and to a light-emitting apparatus, which has at least one LED light source and a corresponding arrangement.

It is known from the prior art to convert the light emitted by LED light sources at least partially into light of a different wavelength. The reason for this is that, with the aid of LEDs alone, it is not possible to generate light of any desired color or color temperature. Until now, only semiconductors have been available which emit light in a few colors, wherein, in this case too, the efficiency of the light emission fluctuates significantly. A known arrangement for light emission therefore often consists in an LED which emits light in the blue wavelength range, i.e. light with a comparatively high energy, wherein this light is then converted at least partially into light of a different wavelength with the aid of a color conversion material. As a result, white light or light of another resulting mixed color is then ultimately emitted as mixed light. The color conversion material in this case contains corresponding active ingredients, for example fluorescent dyes or phosphors, which absorb the light originating from the LED and emit it again at a different wavelength. Recently, materials have also been used which contain so-called quantum dots. In this case too, a material results which has properties comparable to the dyes.

In the case of such a procedure for converting the light originating from a light source, there is of course the desire to configure the color conversion to be as efficient as possible. In particular, as little light as possible should be lost, which can then no longer be used for actual light emission. In addition, the color conversion material should influence as much light as possible in respect of its wavelength in the desired manner.

The present invention is therefore based on the problem of specifying arrangements for converting the light emitted by an LED light source which have advantages in terms of their efficiency in comparison with previously known corresponding arrangements.

The object is achieved by an arrangement for converting the light emitted by an LED light source having the features of one of the independent claims. Advantageous developments of the invention are the subject matter of the dependent claims.

The solutions described below in this case start from two different variants known from the prior art which have been improved in an inventive manner.

The starting point for a first solution according to the invention is in this case an arrangement in which a light emission element is arranged downstream of the color conversion element, which light emission element forms a light emission surface of the arrangement for converting the light on a side remote from the color conversion element. In accordance with the invention, provision is made here for the light emission surface of the light emission element to be structured.

In accordance with a first aspect of the present invention, therefore, an arrangement for converting the light emitted by an LED light source is proposed which has a color conversion element which is designed to convert the light originating from an LED at least partially into light of a different wavelength, as well as a preferably plate-shaped light emission element, which is arranged downstream of the color conversion element and forms a light emission surface of the arrangement on a side remote from the color conversion element, wherein the light emission surface is structured in accordance with the invention.

A likewise known arrangement envisages that the color conversion element is arranged between two substantially plate-shaped, transparent elements, wherein one of said elements forms a light coupling-in element, which forms a light coupling-in surface of the arrangement on a side remote from the color conversion element, and wherein the second element forms a light emission element, which in turn forms a light emission surface of the arrangement on a side remote from the color conversion element. In this embodiment, provision is made in accordance with the invention for the light coupling-in surface and/or the light emission surface of the arrangement to be structured.

In accordance with a second aspect of the present invention, accordingly an arrangement for converting the light emitted by an LED light source is proposed which has a color conversion element, which color conversion element is designed to convert the light originating from an LED at least partially into light of a different wavelength, and a preferably plate-shaped light coupling-in element, which is arranged upstream of the color conversion element and which forms a light coupling-in surface of the arrangement on a side remote from the color conversion element, as well as a likewise preferably plate-shaped light emission element, which is arranged downstream of the color conversion element and which forms a light emission surface of the arrangement on a side remote from the color conversion element, wherein, in accordance with the invention, the light coupling-in surface and/or the light emission surface of the arrangement are structured.

The structuring of the light emission surface and/or of the light coupling-in surface can be performed in a variety of ways, wherein it would be conceivable, for example, to structure, for example roughen up, at least one of the surfaces so as to be light-scattering. Depending on the surface on which the light-scattering structuring is provided, different effects then result, but both of these effects contribute to an increase in the efficiency of the arrangement. If, for example, the light emission surface is structured so as to be light-scattering, this results in some of the light being reflected at the scattering structures of the light emission surface into the region of the color conversion element. In this case, therefore, at least partially so-called multiple reflections result, which overall lead to the possibility of more efficient use of the conversion element and mean that correspondingly less material is required for this than is the case in solutions known from the prior art. A scattering configuration of the light coupling-in surface, on the other hand, means that the light originating from the LED light source is already distributed as the light enters the arrangement in such a way that it is conducted through the color conversion element more efficiently. In turn, this color conversion element can therefore be used more efficiently, with the result that the desired light conversion is optimized.

As an alternative to a light-scattering structuring, a microprism structure could also be used. The use of such a structure on the light exit surface in turn results in the advantageous multiple reflections already mentioned. When used on the light entry surface, the structure has the effect that the excitation light emitted by the light source is coupled in more efficiently and back-reflections occurring at this surface are avoided. In both cases, therefore, an increase in efficiency is again achieved, wherein both surfaces do not necessarily need to be embodied in the same way, but in particular also a combination of scattering light entry surface and light exit surface provided with microprisms, or vice versa, would be conceivable, for example.

For the case where the color conversion element is arranged between two transparent, plate-shaped elements, the LED light source is arranged outside this arrangement. As an alternative to this, however, the light coupling-in element could also be dispensed with, in which case it would be conceivable, for example, to embed or integrate the LED directly in the color conversion element.

A further arrangement according to the invention for converting the light originating from an LED light source is based on the use of a color conversion element in which the light originating from the LED is coupled in to said color conversion element at a first surface and is emitted again via a second surface, which is separated from the light entry surface and is preferably oriented at a right angle thereto. In order to increase the efficiency in such an arrangement, it is known from the prior art to provide at least that side which is opposite the light exit surface with a mirror coating.

Against the background of this second known arrangement, it is now proposed in accordance with the invention to form the mirror arrangement by means of a so-called metamaterial. This is characterized by the fact that light is not reflected at the surface in such a way that the known law of angle of incidence=angle of reflection applies, as in the case of a conventional mirror surface. Instead, in the case of such a material, impinging light beams are reflected in the opposite direction irrespective of their angle of incidence. The use of such a mirroring metamaterial results in the loss of light beams in the color conversion element being reduced and therefore in turn in the efficiency thereof being increased.

In accordance with a third aspect in accordance with the invention, therefore, an arrangement for converting the light emitted by an LED light source is proposed which has a color conversion element, which is designed to convert the light originating from an LED at least partially into light of a different wavelength, wherein the color conversion element has at least one first surface, which forms a light entry surface for the light of the LED light source, and a light exit surface, which is separate from the light entry surface and is preferably oriented at a right angle thereto, and wherein one side of the element which is opposite the light exit surface is provided with a mirror arrangement. In accordance with the invention, this mirror arrangement is formed by a metamaterial.

Preferably, the color conversion element is approximately in the form of a right-parallelepiped, wherein, apart from the light entry surface and the light exit surface, possibly all other sides of the color conversion element can also be provided with a mirror arrangement. For the further surfaces, however, in this case the use of a conventionally mirroring material is sufficient or even advantageous.

The color conversion elements used in the arrangements in accordance with the invention comprise, as already mentioned, a material which absorbs the light originating from the LED light source and emits it again as light with a changed wavelength range. These may be phosphors and the quantum dots already mentioned above.

The invention will be explained in more detail below with reference to the attached drawing, in which:

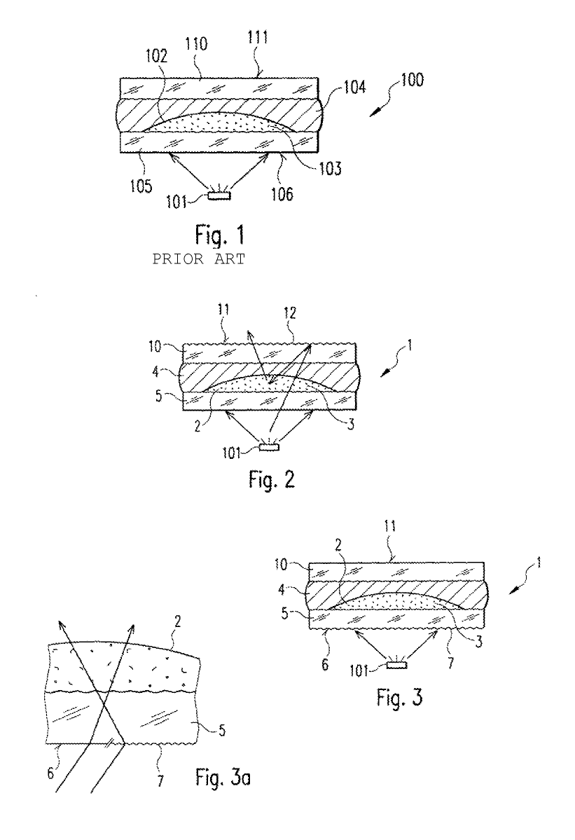

FIG. 1 shows an arrangement for converting the light emitted by an LED light source corresponding to the prior art;

FIG. 2 shows an exemplary embodiment according to the invention of an arrangement for converting LED light;

FIG. 3 shows a second exemplary embodiment according to the invention of an arrangement for converting LED light;

FIG. 3a shows an enlarged illustration of FIG. 3 for illustrating the function of the light-scattering light coupling-in surface;

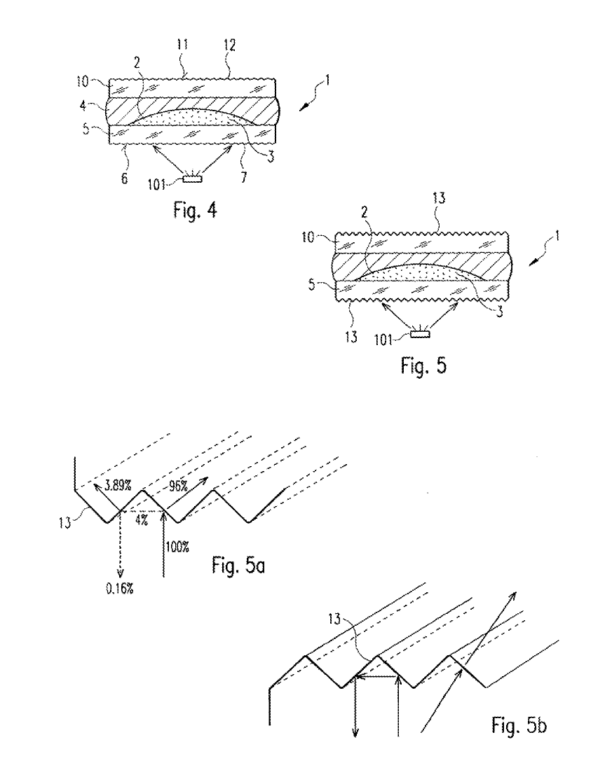

FIG. 4 shows a third exemplary embodiment of an arrangement according to the invention for converting LED light;

FIG. 5 shows a configuration of the light coupling-in surface and the light emission surface having microprisms;

FIGS. 5a and 5b show enlarged illustrations of the exemplary embodiment shown in FIG. 5;

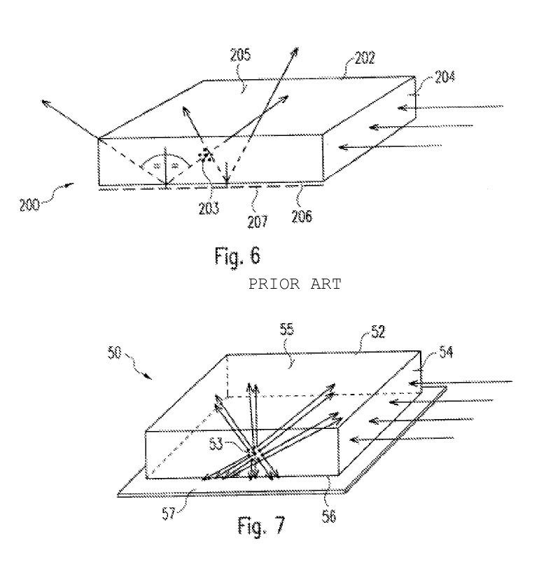

FIG. 6 shows a further arrangement, known from the prior art, for converting LED light; and

FIG. 7 shows a development according to the invention of the arrangement illustrated in FIG. 6.

As the starting point for the first exemplary embodiments in accordance with the invention explained below, FIG. 1 shows an arrangement for converting the light emitted by an LED light source, as is known from the prior art. This arrangement, which is generally provided with the reference symbol 100, is intended to be arranged at a certain distance in front of the LED light source 101. The distance or the dimensions should in this case be selected such that the light emitted by the LED light source 101 generally in a comparatively large angular range substantially completely hits the arrangement 100.

A color conversion element 102 provided in the arrangement which consists of a transparent material having particles 103 for color conversion located therein is responsible for the conversion of the light from the LED light source 101. These individual elements for color conversion can, as already mentioned, be formed by so-called phosphors 103 or so-called quantum dots. Light impinging on the particles 103 is absorbed and emitted again at a different wavelength.

The color conversion element 102 is in this case approximately in the form of a lens and is embedded between two transparent elements 105 and 110. The first plate-shaped element 105, which is formed by a pane of glass, for example, forms a light coupling-in element, on which the color conversion element 102 is arranged. The light emission element 110, which is likewise formed by a flat pane of glass, is arranged on the opposite side. The two panes of glass 105 and 110 are primarily used as protection for the color conversion element 102, wherein said color conversion element is embedded with the aid of an adhesive 104 between the two plates 105 and 110. As a result, a compact and stable, overall plate-shaped unit is formed. The inner faces of the light coupling-in element 105 and the light emission element 110 which face the adhesive 104 and the color conversion element 102, respectively, can in this case be slightly structured so as to improve the connection to the adhesive 104, which does not have any substantial influence on the light emission or the efficiency of the arrangement 100, however, owing to the fact that adhesive and glass have comparatively similar indices of refraction. The two outer surfaces of the arrangement, on the other hand, i.e. the surface 106 facing the light source 101 and the light emission surface 111 remote from the color conversion element 102 are flat in accordance with the prior art.

Different variants are described below for improving the arrangement illustrated in FIG. 1 in terms of its efficiency. A first possibility in this regard is illustrated in FIG. 2, wherein the arrangement 1 according to the invention is again formed consisting of the three layers light coupling-in element 5, color conversion element 2 and light emission element 10, and wherein the embedding of the color conversion element 2 between the light coupling-in element 5 and the light emission element 10 again takes place with the aid of an adhesive 4. In addition, the arrangement is arranged at a certain distance from an LED light source 101, in the same way as the arrangement known from the prior art and illustrated in FIG. 1.

In this first exemplary embodiment in accordance with the invention shown in FIG. 2, provision is now made for the surface of the light emission element 10 which is remote from the color conversion element 2, i.e. the light emission surface 11, to be structured. In particular, in the variant illustrated in the exemplary embodiment shown in FIG. 2, the light emission surface 11 is provided with a light-scattering structure, which is provided with the reference symbol 12. As indicated, this light-scattering structure 12 has the result that impinging light beams are at least partially reflected back and again enter the color conversion element 2. Light which has not yet been converted the first time it passed through the color conversion element 2 can in this case therefore be reflected back again and there is a further opportunity for it to be converted. Owing to the use of the light-scattering structure 12, multiple reflections therefore take place, by means of which the efficiency of the color conversion element 2 or of the arrangement as a whole is increased.

For example, provision can be made for blue light to be emitted by the LED 101, which light is intended to be converted into red light by the dyes or quantum dots 3 in the color conversion element 2. Blue light which passes undisrupted through the color conversion element 2, however, is then scattered back at least partially at the structure 12 in such a way that it enters the color conversion element 2 once again. As already mentioned, this correspondingly then results in this light also having the possibility of being converted and therefore the efficiency of the color conversion being increased.

A second exemplary embodiment according to the invention of an arrangement for converting light is illustrated in FIG. 3 and FIG. 3a, wherein identical elements have been provided with the same reference symbols.

In the variant shown in FIG. 3, provision is made for the light coupling-in surface 6 of the light coupling-in element 5 to now have the possibility of being provided with a structuring 7, wherein, in the present case, a light-scattering structuring is again provided. The resultant effect here is illustrated in FIG. 3a, in which it can be seen that, owing to the light-scattering structuring 7, which can be achieved by corresponding roughening of the surface 6, for example, the angles of incidence of the incoming light are changed. In particular, light beams are scattered or deflected in such a way that they cover a longer path through the color conversion element 2. Necessarily, the probability of a corresponding light beam impinging on a color conversion particle 103 and correspondingly being converted into light of a different wavelength is thus increased. The variant in FIGS. 3 and 3a therefore also contributes to an increase in efficiency.

FIG. 4 finally shows a variant which illustrates a combination of the exemplary embodiments in FIGS. 2 and 3. In this case, therefore, both the coupling-in surface 6 and the light emission surface 11 are structured, in particular provided in each case with a light-scattering structure. The effects illustrated in connection with FIGS. 2 and 3 in this case contribute independently of one another to an increase in the efficiency of the color conversion.

As an alternative to a scattering structuring of the light coupling-in surface and/or the light emission surface, however, structuring with microprisms 13 could also be provided, as is illustrated schematically in FIG. 5. In the exemplary embodiment illustrated, elongate microprisms 13 which are approximately triangular in cross section are provided both on the upper side and on the lower side of the arrangement 1. The prism structure on the light coupling-in surface 5 in this case has the effect that light can enter the arrangement 1 more efficiently. In the case of a blue excitation light, generally a beam which impinges on a flat surface perpendicularly is reflected at approximately 4%. These losses, which result in a reduction in the efficiency of the arrangement, can be reduced with the aid of the prism structure since in this case the reflection losses are markedly below 1%. In addition, as illustrated using the light beams in FIG. 5a, an angled profile of the penetrating light beams results, as a result of which, in turn, the path within the color conversion element 2 is extended and, correspondingly, increased color conversion occurs.

The prism structure on the light exit surface 11, on the other hand, has the effect that light beams which impinge substantially perpendicularly and which have therefore not been color-converted are reflected back, as is illustrated in FIG. 5b. In this case too, the multiple reflections described already in connection with the roughening can therefore be achieved, by means of which light which has initially passed through the color conversion element 2 uninfluenced is reflected into this element 2 so that there is once again the possibility of color conversion.

Even the use of such prism structures therefore contributes to an increase in the efficiency of the color conversion, wherein these prism structures could be combined with the abovementioned light-scattering structures in any desired manner. That is to say that it would be quite possible for a prism structure to be provided on the light coupling-in surface 6 while, on the other hand, the light emission surface 11 is provided with a light-scattering structure. A reverse configuration of the two surfaces 6 and 7 would also be conceivable.

Furthermore, it would also be conceivable to dispense with the light coupling-in element 5 in the arrangement according to the invention. In this case, the light source 101 could then be embedded directly in the color conversion element 2 or the arrangement 1 can then be fitted directly on the printed circuit board on which the LED is generally mounted. In this case, a corresponding structuring of the light emission surface is then in any case provided in the manner in accordance with the invention, wherein again a scattering structuring or the use of a microprism structure can be provided.

For the exemplary embodiment in accordance with the invention described below, another arrangement known from the prior art for color conversion of LED light is used as a starting point. This known arrangement 200, which is illustrated in FIG. 6, consists of a color conversion element 202 which is approximately in the form of a right-parallelepiped or plate and which contains the color conversion particles 203, i.e. phosphors or quantum dots. Excitation light is in this case radiated into the element 202 via a side surface 204. Once light has been converted by the corresponding phosphors 203, it is emitted via a light emission surface 205, which is separate from the light entry surface 204, which light emission surface is oriented in particular through 90° with respect to said light entry surface. Preferably, the light emission surface 205 is a flat side of the color conversion element 202 which is plate-shaped or in the form of a right-parallelepiped, with the result that a light emission with as large an area as possible is achieved.

In order to prevent light being emitted at the flat side 206 which is opposite the light exit surface 205 which would represent lost light, in accordance with the prior art a mirror coating 207 is provided. Impinging light beams are reflected as illustrated schematically, but some of the light beams then leave the color conversion element 202 possibly via further side surfaces and are correspondingly lost.

In accordance with the present invention, provision is made in order to improve this known arrangement for a mirror arrangement to be used in place of the conventional mirror coating 207 corresponding to the illustration shown in FIG. 7, which mirror arrangement is formed by a so-called metamaterial.

In principle, the design of the arrangement 50 in FIG. 7 corresponds to that in FIG. 6, i.e. a color conversion element 52 in the form of a plate or right-parallelepiped is provided, which color conversion element contains the dyes or quantum dots 53, and one side surface of said color conversion element forms a light entry surface 54 for the excitation light originating from an LED light source (not illustrated). Instead of the mirror arrangement, the above-mentioned metamirror 57 is now provided on the side 56 opposite the light emission surface 55, however. Such metamirrors consist of a material which is characterized by the fact that, as illustrated, impinging light beams are reflected back in the opposite direction. The conventional “angle of incidence=angle of reflection” law therefore does not apply, but rather the light beams are sent back precisely in that direction from which they impinge on the surface of the metamirror 57.

This particular type of deflection of impinging light beams results in fewer beams having the possibility of emerging as lost light via the side surfaces of the color conversion element 52 and correspondingly in turn in the efficiency of the color conversion being increased. The converted light then in turn leaves the element via the light emission surface 55.

In all described variants, therefore, the efficiency of the conversion of light can be increased in comparison with solutions known from the prior art. The increase in efficiency in this case in particular has the result that a smaller quantity of color conversion material is required and light losses are reduced. Both advantages contribute to the fact that light sources on an LED basis can be used in a variety of ways for lighting purposes.

1. An arrangement for converting the light emitted by an LED light source, said arrangement having a color conversion element, which is designed to convert the light originating from an LED light source at least partially into light of another wavelength, and a preferably plate-shaped light emission element, which is arranged downstream of the color conversion element and forms a light emission surface of the arrangement on a side remote from the color conversion element,
wherein the light emission surface is structured.

2. An arrangement for converting the light emitted by an LED light source, said arrangement having a color conversion element), which is designed to convert the light originating from an LED light source at least partially into light of a different wavelength, and a preferably plate-shaped light coupling-in element, which is arranged upstream of the color conversion element and which forms a light coupling-in surface of the arrangement on a side remote from the color conversion element, and a preferably plate-shaped light emission element which is arranged downstream of the color conversion element and forms a light emission surface of the arrangement on a side remote from the color conversion element,
wherein the light coupling-in surface and/or the light emission surface are structured.

3. The arrangement as claimed in claim 1,
wherein at least one of the surfaces is structured so as to be light-scattering.

4. The arrangement as claimed in claim 1,
wherein at least one of the surfaces is provided with a prism structure.

5. The arrangement as claimed in claim 1,
wherein the color conversion element is in the form of a lens.

6. An arrangement for converting the light emitted by an LED light source, said arrangement having a color conversion element, which is designed to convert the light originating from an LED light source at least partially into light of a different wavelength, wherein the color conversion element has at least one first surface which forms a light entry surface for the light of the LED light source, and a light exit surface, which is separate from the light entry surface and is preferably oriented at a right angle thereto, wherein a side of the color conversion element which is opposite the light exit surface is provided with a mirror arrangement,
wherein the mirror arrangement is formed by a metamirror.

7. The arrangement as claimed in claim 6,
wherein the color conversion element is approximately in the form of a right-parallelepiped.

8. The arrangement as claimed in claim 1,
wherein the color conversion element contains phosphors.

9. The arrangement as claimed in claim 1,
wherein the color conversion element contains quantum dots.

10. The arrangement for light emission comprising an LED light source and an arrangement for converting the light emitted by the LED light source as claimed in claim 1.
